(19) United States
(12) Patent Application Publication
(10) Pub. No.: US 2016/0353586 A1
(43) Pub. Date: Dec. 1, 2016

(54) DISPLAY DEVICE HAVING CASE AND COVER

(71) Applicant: HON HAI PRECISION INDUSTRY CO., LTD., New Taipei (TW)

(72) Inventors: FANG-WEI LUO, New Taipei (TW); JEN-HUI OH, New Taipei (TW); CHING-HUA TSAI, New Taipei (TW); CHIH-PING CHEN, New Taipei (TW); KUANG-LUNG LIN, New Taipei (TW)

(21) Appl. No.: 14/788,394

(22) Filed: Jun. 30, 2015

(30) Foreign Application Priority Data
May 28, 2015 (CN) 201510281018.8

(51) Int. Cl. H05K 5/00; H05K 5/02; H05K 5/03

(52) U.S. Cl. CPC H05K 5/0017; H05K 5/03; H05K 5/0221; H05K 5/0004

(57) ABSTRACT

A display device includes a case, a display panel received in the case and a lateral cover coupled to the case. The case includes a main body, an extension body extending from the main body and a frame extending from the main body. The main body and the extension body cooperatively define an opening between the main body and the extension body. The display panel is received between the main body and the frame via the opening. The display panel has a periphery surrounded by the main body and the frame. The lateral cover covers the opening and is coupled to the main body and the extension body.

### FIELD

The subject matter herein generally relates to display devices.

### BACKGROUND

Display devices are used widely in TVs, tablet personal computers, notebook computers, digital cameras or other electronic devices. The display device generally includes a display panel and a case holding the display panel.

### BRIEF DESCRIPTION OF THE DRAWINGS

Implementations of the present technology will now be described, by way of example only, with reference to the attached figures.

FIG. 1 is an assembled, isometric view of a display device in accordance with an embodiment of the present disclosure.

FIG. 2 is an exploded, isometric view of the display device in FIG. 1.

FIG. 3 is an isometric view of a case of the display device in FIG. 2.

FIG. 4 is an enlarged view of a circled part IV of the case in FIG. 3.

FIG. 5 is an isometric view of the case in FIG. 3, but viewed from a different angle.

FIG. 6 is an isometric view of a lateral cover of the display device in FIG. 2.

FIG. 7 is an isometric view of the lateral cover in FIG. 6, but viewed from a different angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to a display device. The display device includes a case, a display panel received in the case and a lateral cover coupled to the case. The case includes a main body, an extension body extending from the main body and a frame extending from the main body. The main body and the extension body cooperatively define an opening between the main body and the extension body. The display panel is received between the main body and the frame via the opening. The display panel has a periphery surrounded by the main body and the frame. The lateral cover covers the opening and is coupled to the main body and the extension body.

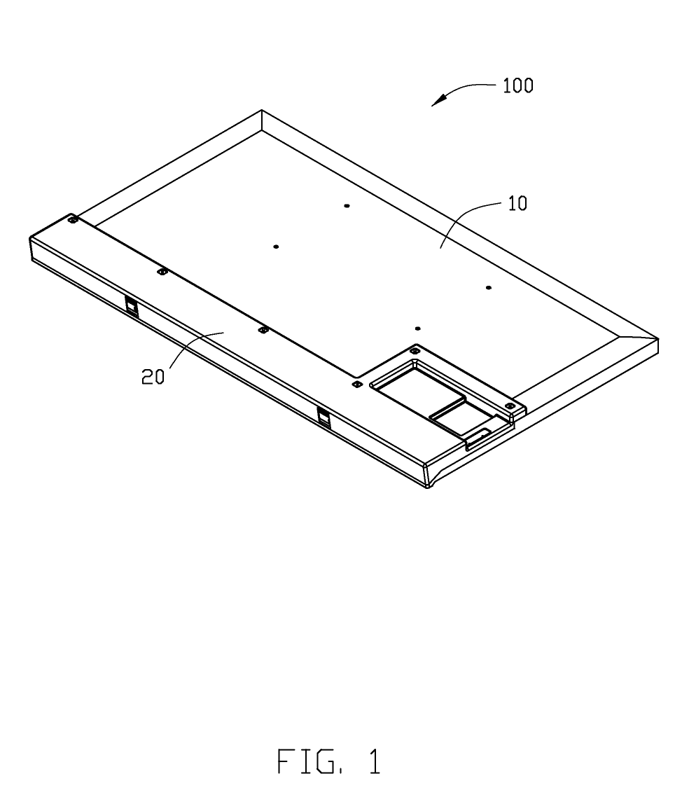

FIG. 1 illustrates a display device 100 of an embodiment of the present disclosure. The display device 100 is used for TVs, tablet personal computers, notebook computers, digital cameras or other electronic devices. The display device 100 can be a liquid crystal display device or a light emitting diode display device. The display device 100 can include a case 10, a lateral cover 20 and a display panel 30 received in the case 10 and the lateral cover 20.

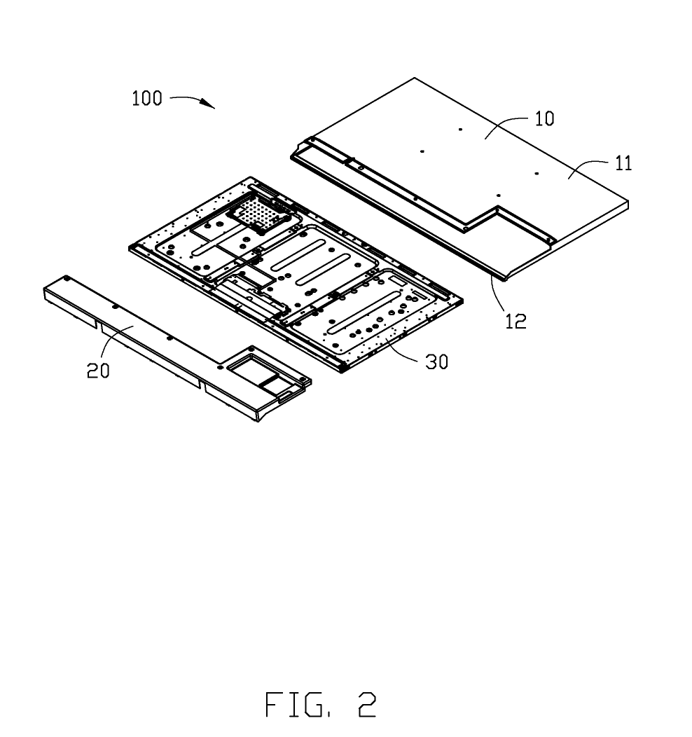

FIG. 2 illustrates that the case 10 can include a main body 11 and an extension body 12 integrally extending from two ends of the main body 11. The case 11 can be made of plastic material. The main body 11 and the extension body 12 cooperatively define an opening 110 therebetween.

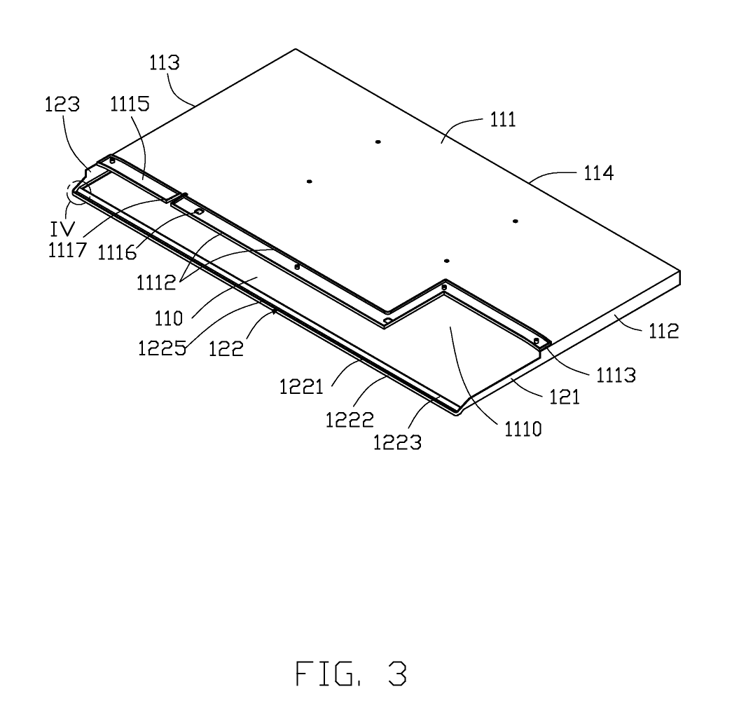

FIG. 3 illustrates that the main body 11 including a base 111, a first sidewall 112, a second sidewall 113 and a third sidewall 114 extending downwards from three connecting edges of the base 111. The first sidewall 112, the second sidewall 113 and the third sidewall 114 each are substantially perpendicular to the base 111. The first sidewall 112, the second sidewall 113 and the third sidewall 114 are located at a side of the base 111. The first sidewall 112 is parallel and opposite to the second sidewall 113. The third sidewall 114 is perpendicular to and connecting the first sidewall 112 and the second sidewall 113. The base 111 includes a free edge opposite to the third sidewall 114. The base 111 defines a cutout 1110 at a corner adjacent to the free edge, thereby the free edge of the base 111 being in a zigzag configuration. In this disclosure, the zigzag configuration can include a first portion, a second portion substantially parallel the first portion, and a third portion connecting between the first portion and the second portion, the third portion can be substantially perpendicular to the first portion and the second portion. In at least one embodiment, the cutout 1110 is rectangular. The cutout 1110 can be a portion of the opening 110.

A first flange 1112 extends outward from the free edge of the base 111, and a second flange 1112 extends from the base 111 adjacent to the free edge of the base 111. The first flange 1112 and the second flange 1112 extend along a direction parallel the free edge. The first flange 1112 and the second flange 1112 are parallel to each other. The first flange 1112 and the second flange 1112 are substantially perpendicular to the base 111. The first and second flanges 1112 each extend from the first sidewall 112 to the second sidewall 113. Two opposite connecting flanges 1113 connect corresponding ends of the first, second flanges 1112. The two connecting flanges 1113 can be coplanar with the first sidewall 112 and the second sidewall 113, respectively. The first and second flanges 1112 cooperative define a latch groove 1115 between the two connecting flanges 1113. Each of the first flange 1112 and the second flange 1112 each are in a zigzag configuration similar to the free edge of the base 111. The latch groove 1115 is in a zigzag configuration. The base 111 can define a plurality of through apertures 1116 in the latch groove 1115. A number of the through apertures 1116 can be two. The main body 11 can further define a slit 1117 across the latch groove 1115 adjacent to the second sidewall 113, The slit 1117 extends through the base 111, the first and second flanges 1112 adjacent to the second sidewall 113.

The extension body 12 can include a first extension arm 121 extending from a distal end of the first sidewall 112, a second extension arm 123 extending from a distal end of the second sidewall 113, and a coupling part 122 connecting between the first extension arm 121 and the second extension arm 123. The first extension arm 121 and the first sidewall 112 are coplanar. The first extension arm 121 has an upper edge lower than the edge where the first sidewall 112 extends. A height of the first extension arm 121 is half of a height of the first sidewall 112. The first extension arm 121 has an end portion adjacent to the coupling part 122 decreasing in height along a direction toward the coupling part 122. The second extension arm 123 and the second sidewall 113 are coplanar. A portion of the second extension arm 123 adjacent to the second sidewall 113 has an upper edge being flush with the edge where the second sidewall 113 extends. Another portion of the second extension arm 123 adjacent to coupling part 122 has an upper edge decreasing in height along a direction toward the coupling part 122. The first extension arm 121 has a distal end adjacent to the coupling part 122. Additionally the first extension arm 121 can be bent downward. The second extension arm 123 has a distal end adjacent to the coupling part 122. Additionally the second extension arm 123 can be is bent downward. The coupling part 122 connects the distal ends of the first extension arm 121 and the second extension arm 123. The coupling part 122 is located at a level below a level where the base 111 is located. The coupling part 122 and the free edge of the base 111 are located at two opposite sides of the opening 110, respectively.

In at least one embodiment, the opening 110 is surrounded by the free edge of the base 111, the first flange 1112, the first extension arm 121, the coupling part 122 and the second extension arm 123. The opening 110 is substantially L-shaped.

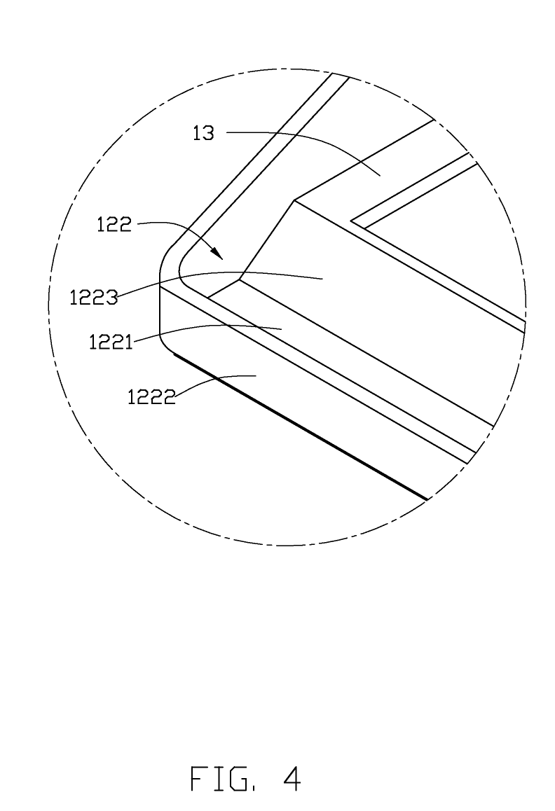

FIGS. 3 and 4 illustrate that the coupling part 122 can include a base wall 1221, a blocking wall 1222 extending upwardly from an outer edge of the base wall 1221, and an inner wall 1223 extending upwardly from an inner edge opposite to the outer edge of the base wall 1221. The blocking wall 1222 is substantially perpendicular to the base wall 1221. The inner wall 1223 is angled relative to the base wall 1221. The base wall 1221, the blocking wall 1222 and the inner wall 1223 cooperatively define receiving groove 1225 between the distal ends of the first extension arm 121 and the second extension arm 123. In at least one embodiment, the blocking wall 1222 can include a plurality of locking configurations in the receiving groove 1225 for coupling the lateral cover 20.

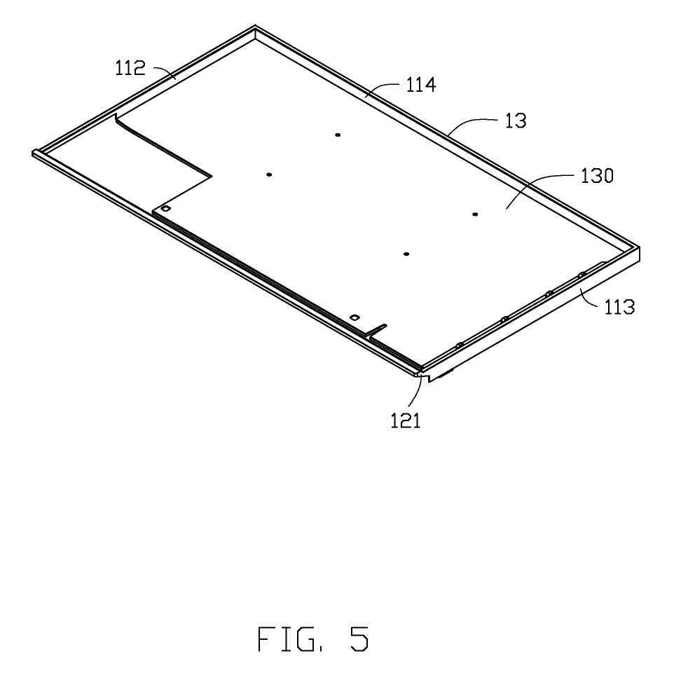

FIG. 5 illustrates that the case 10 further includes a frame 13 integrally extending from the main body 11 and the extension body 12. The frame 13 extends from bottom edges of the first sidewall 112, the second sidewall 113, the third sidewall 114, the first extension arm 121, and the second extension arm 123 toward a center of the main body 11. The frame 13 has a periphery flushed with peripheries of the first sidewall 112, the second sidewall 113, the third sidewall 114, the first extension arm 121 and the second extension arm 123. The frame 13 is substantially parallel to the base 111. The base 111, the first sidewall 112, the second sidewall 113, the third sidewall 114, the first extension arm 121, the second extension arm 123, the frame 13 and the coupling part 122 cooperative define a receiving room 130 for receiving the display panel 30. A distance between base 111 and the frame 13 can be substantially equal to a thickness of the display panel 30. A perpendicular distance between the coupling part 122 and the base 111 can be substantially equal to the thickness of the display panel 30. In at least one embodiment, the frame 13, the main body 11 and the extension body 12 are an integral one.

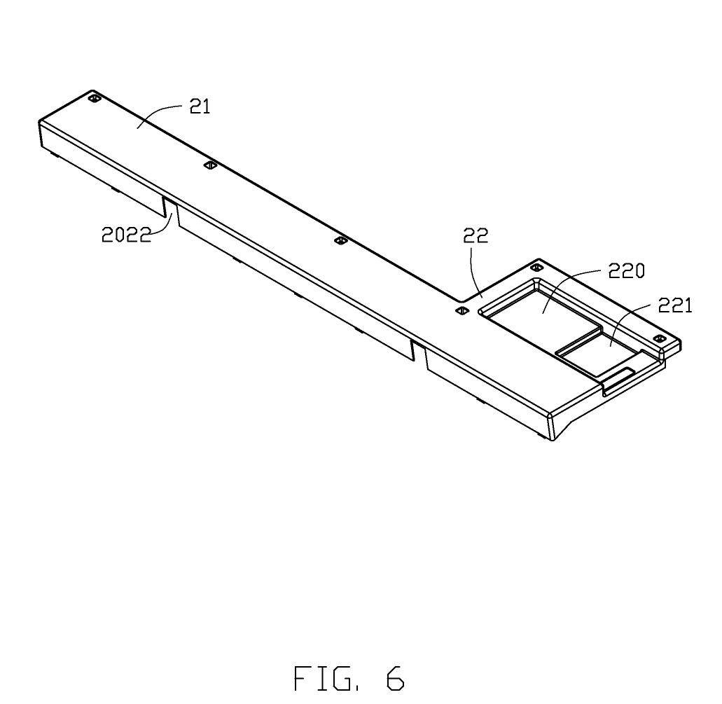

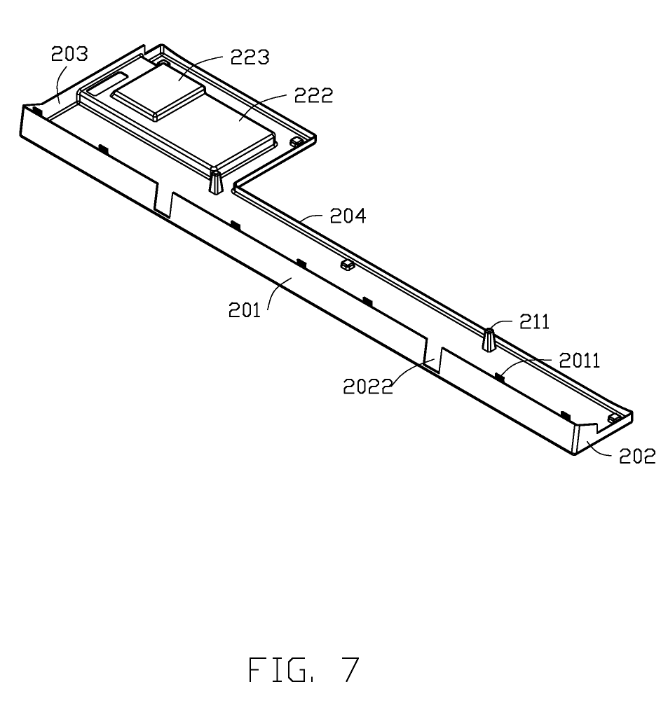

FIGS. 6 and 7 illustrate that the lateral cover 20 can include a main portion 21 and an extension portion 22 integrally extending from main portion 21. The main portion 21 and the extension portion 22 cooperatively define an L-shaped configuration, which is similar to that of the opening 110.

The main portion 21 includes a plurality of poles 211 extending from an inner face thereof toward the through apertures 113 in the base 111 for coupling the lateral cover 20 to the case 10.

The extension portion 22 includes a first concave 220 descending along a direction from an outer face toward the inner face of the extension portion 22. The extension portion 22 further includes a second concave 221 descending from a portion of the first concave 220 along a direction from an outer face toward the inner face of the first concave 220. The second concave 221 is adjacent to a lateral end of the first concave 220. The first concave 220 and the second concave 221 cooperatively form a configuration of steps. Correspondingly, the extension portion 22 includes a first convex 222 extending from the inner face of the extension portion 22 and corresponding to the first concave 220 and a second convex 223 extending from the inner face of the convex 222 and corresponding to the second concave 221. The second convex 223 extends beyond the first convex 222. The first concave 220 and the first convex 222 each have a size substantially equal to that of the cutout 1110. The first concave 220 is rectangular. The second concave 221 is rectangular. The first convex 222 and the second convex 223 each are rectangular.

The lateral cover 20 further includes a coupling configuration extending from edges of the main portion 21, for coupling the main body 11 and the extension body 12 of the case 10. The coupling configuration can include a first coupling wall 201, a second coupling wall 202, a third coupling wall 203 and a fourth coupling wall 204 extending from connecting edges of the main portion 21. The first coupling wall 201, the second coupling wall 202, the third coupling wall 203 and the fourth coupling wall 204 are substantially perpendicular to the main portion 21. The first coupling wall 201, the second coupling wall 202, the third coupling wall 203 and the fourth coupling wall 204 are interconnecting with each other. The first coupling wall 201 is opposite to the fourth coupling wall 204. The second coupling wall 202 is parallel to the third coupling wall 203. The fourth coupling wall 204 is in a zigzag configuration. The poles 211 are adjacent to the fourth coupling wall 204.

The first coupling wall 201 is configured to couple the coupling part 122 and includes a plurality of snaps 2011 and a plurality of mounting slots 2022. The snaps 2011 are configured to couple the locking configurations of the blocking wall 1222. The mounting slots 2022 are configured to couple the display panel 30. The second coupling wall 202 is configured to couple the second extension arm 123 and has a configuration complementary to that of the second extension arm 123. The second coupling wall 203 is configured to couple to the first extension arm 121 and has a configuration complementary to that of the first extension arm 121. The fourth coupling wall 204 is configured to be received in the latch groove 1115, and has a height less than that of the first coupling wall 201, the second coupling wall 202 and the third coupling wall 204.

The display panel 30 is configured to display. The display panel 30 is substantially rectangular. The display panel 30 can be a liquid crystal display panel or a light emitting diode display panel. The display panel 30 can be a twisted nematic (TN) display panel, a vertical alignment (VA) display panel, an in-plane switching (IPS) display panel, or a continuous pinwheel alignment (CPA) display panel. The display panel 30 includes a display face and a coupling face opposite to the display face.

In an assembly, the display panel 30 is positioned in the case 10 via the opening 110, the display panel has a periphery thereof surrounded by the main body 11 of the case 10 and the frame 13. In details, the display panel 30 has three side portions each located between the frame 13 and the base 111, another side portion extends toward the coupling part 122. The another side portion of the display panel 30 can be coupled to the coupling part 122. The three side portions of the display panel 30 are surrounded by the frame 13, the base 111, the first sidewall 112, the second sidewall 113 and the third sidewall 114. The display face of the display panel 30 is exposed out of the frame 13, with three edges thereof at the three side portions of the display panel 30 abutted against by the frame 13 toward the base 111. The lateral cover 20 is coupled to the case 10 and covers on the opening 110. In details, the first convex 222 of the lateral cover 20 is coupled in the cutout 1110 of the base 111. The second convex 223 of the lateral cover 20 can abut against the display panel 30. The first coupling wall 201 of the lateral cover 20 couples the coupling part 122 with a free end of the coupling wall 201 received in the receiving groove 1225 of the coupling part 122. The snaps 2011 of the first coupling wall 201 couple the locking configurations of the blocking wall 1222 of the coupling part 122. The mounting slots 2022 of the first coupling wall 201 couple the display panel 30. The second coupling wall 202 of the lateral cover 20 couples the second extension arm 123. The third coupling wall 203 couples to the first extension arm 121. The fourth coupling wall 204 is received in the latch groove 1115 of the main body 11. The poles 211 of the main portion 21 of the lateral cover 20 are received in corresponding through apertures 113 of the base 111 in the latch groove 1115. The coupling face of the display panel 30 can contact the base 111 and the main portion 21, the extension portion 22 of the lateral cover 20.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A display device comprising:
a case comprising a main body, an extension body extending from the main body and a frame extending from the main body, the main body and the extension body cooperatively defining an opening between the main body and the extension body;
a display panel received between the main body and the frame via the opening, the display panel having a periphery being surrounded by the main body and the frame; and
a lateral cover covering the opening and coupled to the main body and the extension body.

2. The display device of claim 1, wherein the main body comprises a base, first sidewall, a second sidewall and a third sidewall extending from edges of the base.

3. The display device of claim 2, wherein the first sidewall, the second sidewall and the third sidewall are perpendicular to the base.

4. The display device of claim 2, wherein the base further comprises a free edge opposite to the third sidewall, two flanges extending the base adjacent to and extending along the free edge, the two flanges cooperatively defining a latch groove therebetween.

5. The display device of claim 4, wherein the base defines a cutout adjacent to the first sidewall, the free edge being in a zigzag configuration.

6. The display device of claim 5, wherein the extension body comprises a first extension arm extending from the first sidewall, a second extension arm extending from the second sidewall and a coupling part connecting the first extension arm and the second extension arm, the coupling part being opposite to the free edge.

7. The display device of claim 6, wherein the opening is surrounded by the free edge, the first extension arm, the second extension arm and the coupling part, the cutout being a portion of the opening.

8. The display device of claim 7, wherein the frame extends from edges of the first sidewall, the second sidewall, the third sidewall, the first extension arm, and the second extension arm toward a center of the main body.

9. The display device of claim 8, wherein the display panel has three side portions each located between the frame and the base, another side portion coupled to the connecting part.

10. The display device of claim 9, wherein the three side portion of the display panel are surrounded by the frame, the base, the first sidewall, the second sidewall and the third sidewall.

11. The display device of claim 10, wherein the lateral cover comprises a main portion and extension portion, the extension portion extending a first convex coupled in the cutout of the base.

12. The display device of claim 11, wherein the main portion of the lateral cover extends a plurality of poles received in corresponding through apertures defined in the base in the latch groove.

13. The display device of claim 11, wherein the main portion of the lateral cover extends a first coupling wall, a second coupling wall, a third coupling wall and a fourth coupling wall, the first coupling wall coupling the coupling part, the second coupling wall coupling the second extension arm, the third coupling wall coupling the first extension arm, and the fourth coupling wall being received in the latch groove of the main body of the cover.

14. The display device of claim 13, wherein the coupling part defines a receiving groove, the first coupling wall having a free end received in the receiving groove.

15. A display device comprising:
a case comprising a main body, an extension body integrally extending from the main body and a frame integrally extending from the main body, the main body and the extension body cooperatively defining an opening between the main body and the extension body;
a display panel received between the main body and the frame via the opening, the display panel having a periphery being surrounded by the main body and the frame; and
a lateral cover covering the opening and coupled to the main body and the extension body.

16. The display device of claim 15, wherein the main body defines a plurality of through apertures, the lateral cover extending a plurality of poles received in corresponding through apertures.

17. The display device of claim 16, wherein the extension body includes a coupling part opposite to the main body, the coupling part defining a receiving groove, the lateral cover extending a coupling wall coupled in the receiving groove.

18. The display device of claim 15, the opening is L-shaped.

19. The display device of claim 18, the lateral cover is L-shaped.
